(19) United States
(12) Patent Application Publication
(10) Pub. No.: US 2025/0376421 A1
(43) Pub. Date: Dec. 11, 2025

(54) CERAMICS WITH ADAPTIVE THERMAL COEFFICIENTS AND HIGH FLUORINE RESISTANCE AT HIGH TEMPERATURES

(71) Applicant: Applied Materials, Inc., Santa Clara, CA (US)

(72) Inventors: Katherine WOO, Santa Clara, CA (US); Jennifer Y. SUN, Mountain View, CA (US)

(21) Appl. No.: 18/735,446

(22) Filed: Jun. 6, 2024

(51) Int. Cl. C04B 35/10; C04B 35/04; H01L 21/687

(52) U.S. Cl. CPC C04B 35/10; C04B 35/04; C04B 2235/3206; C04B 2235/3217; C04B 2235/3225; C04B 2235/445; C04B 2235/9669; H01L 21/68757

(57) ABSTRACT

Embodiments described herein generally relate to process for processing ceramic compositions for use in semiconductor processing applications. More specifically, embodiments relate to thermal, fluorine, and plasma resistant ceramic compositions for use in semiconductor processing. In some embodiments, a ceramic composition includes a Group 13 metal based compound, an alkaline-earth metal based compound, a rare earth metal based compound, and a coefficient of thermal expansion (CTE) modifying compound. In some embodiments, a component of a plasma processing chamber includes an outer surface having a ceramic composition. The ceramic composition includes a Group 13 metal based compound, an alkaline-earth metal based compound, a rare earth metal based compound, and a coefficient of thermal expansion (CTE) modifying compound.

### BACKGROUND

### Field

Embodiments of the present disclosure relate to ceramic compositions for use in semiconductor processing. More specifically, embodiments relate to thermal, fluorine, and plasma resistant ceramic compositions for use in semiconductor processing.

### Description of the Related Art

Various semiconductor processing techniques implement one or more ceramic components that are subjected to harsh chemical conductions during high temperature NF₃ plasma processing techniques. Conventional ceramic components used in high temperature NF₃ plasma processing techniques are formed by a bulk material including doped and/or undoped aluminum nitride or aluminum oxide. However, current known ceramics are unable to withstand increasingly harsh thermal and chemical consumer demands (e.g., high temperatures, fluorine exposure, and plasma exposure). Furthermore, attempts to alleviate such thermal and chemical instabilities of such ceramic components come at the expense of other desirable material properties (e.g., high thermal conductivity, high electrical resistivity, low wear rate, etc.).

Thus, there is a need to develop new ceramic materials that address the thermal and chemical instability of conventional ceramic materials, while also maintaining the desired properties of such materials.

### SUMMARY

Embodiments described herein generally relate to processing ceramic compositions for use in semiconductor processing applications. More specifically, embodiments relate to thermal, fluorine, and plasma resistant ceramic compositions for use in semiconductor processing.

In some embodiments, a ceramic composition includes a Group 13 metal based compound, an alkaline-earth metal based compound, a rare earth metal based compound, and a coefficient of thermal expansion (CTE) modifying compound.

In some embodiments, a component of a plasma processing chamber includes an outer surface having a ceramic composition. The ceramic composition includes a Group 13 metal based compound, an alkaline-earth metal based compound, a rare earth metal based compound, and a coefficient of thermal expansion (CTE) modifying compound.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic, side view of a processing chamber, according to embodiments of the disclosure.

FIG. 2A is a schematic, side view of a part used in a processing chamber, according to embodiments of the disclosure.

FIG. 2B is a schematic, side view of a part used in a processing chamber, the part having a ceramic composition with a modified CTE deposited on a surface thereof, according to embodiments of the disclosure.

FIG. 2C is a schematic, side view of a part used in a processing chamber, the part being comprised of a ceramic composition with a modified CTE, according to embodiments of the disclosure.

FIG. 2D is a schematic, side view of a part used in a processing chamber, the part having a ceramic composition with a modified CTE deposited on a surface thereof and a fluoride glass glaze disposed over the exterior surface of the part and the ceramic composition, according to embodiments of the disclosure.

FIG. 2E is a schematic, side view of a part used in a processing chamber, the part being comprised of a ceramic composition with a modified CTE and a fluoride glass glaze disposed over the exterior surface of the part, according to embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to ceramic compositions having coefficient of thermal expansions (CTE) that can be modified for use in high temperature NF₃ plasma processing chambers. In some embodiments, the ceramic compositions of the present disclosure can include a Group 13 metal based compound, an alkaline-earth metal based compound, a rare earth metal base compound, and/or a CTE modifying compound. The ceramic composition of the present disclosure can be tailored to attain a modified CTE favorable for an intended application. The ceramic compositions described herein exhibit resistance to harsh thermal and chemical processing conditions (e.g., high temperatures, fluorine exposure, and plasma exposure), such as conditions that occur during semiconductor processing and manufacturing. Additionally, CTE modifying compound can include a negative thermal expansion (NTE) material allowing for modified CTE control and tunability.

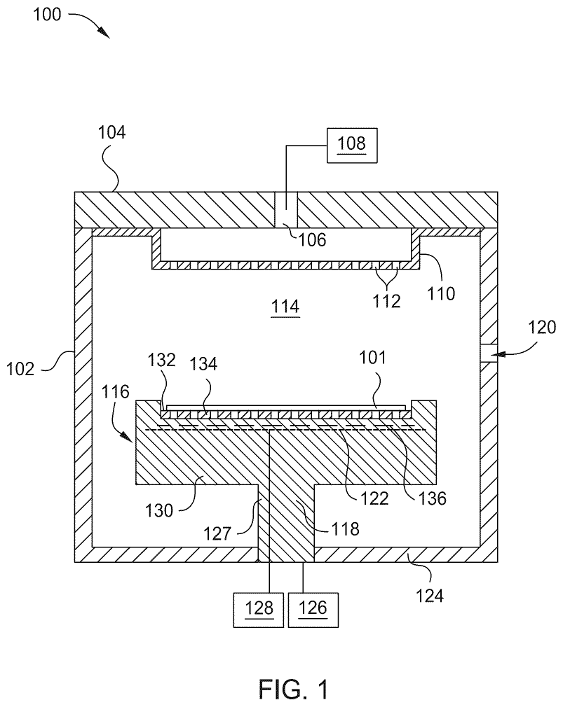

FIG. 1 illustrates a schematic view of a process chamber 100 according to some embodiments of the disclosure. The process chamber 100 includes a chamber body 102 and a lid 104 defining a process volume 114 therein. A bottom 124 of the chamber body 102 is opposite the lid 104. A port 106 is formed through the lid 104. A gas source 108 is in fluid communication with the port 106. A showerhead 110 is coupled to the lid 104. A plurality of openings 112 are formed through the showerhead 110. The gas source 108 is in fluid communication with the process volume 114 via the port 106 and the openings 112.

A substrate support 116 is moveably disposed in the process volume 114 opposite the lid 104. The substrate support 116 includes a support body 130 disposed on a stem 118. The support body 130 includes a support surface 132 disposed opposite the stem 118 and facing the showerhead 110. In some embodiments, the process chamber 100 can include one or more ceramic components including lift pins, edge rings, isolators, heaters, electrostatic chucks, and/or baffles, in which each of the one or more lift pins, edge rings, isolators, heaters, electrostatic chucks, and/or baffles are a ceramic composition of the present disclosure. For example, the support body 130 can include a heater 136 or an electrostatic chuck. The heater 136 or electrostatic chuck is formed from a bulk material. In some embodiments, the heater 136 or electrostatic chuck may be a ceramic composition of the present disclosure.

The support surface 132 can include a plurality of mesas 134. An opening 120 is formed through the chamber body 102 between the lid 104 and the bottom 124. During operation, a substrate 101 is loaded onto the support surface 132 through the opening 120. An actuator 126 is coupled to the substrate support 116 to move the substrate support 116 toward and away from the showerhead 110 for loading and processing the substrate 101 thereon.

An RF mesh 122 is disposed within the support body 130. One or more portions of the RF mesh 122 are disposed in a plane that is substantially perpendicular to the support surface 132. The RF mesh 122 may be used to heat the substrate 101 or electrostatically chuck the substrate 101. The RF mesh 122 is a set distance away from the support surface 132. The RF mesh 122 is connected to one or more RF leads 127. The RF leads 127 are coupled to an RF power source 128. The RF power source 128 provides RF power to the RF mesh 122. While the heater 136 is shown above the RF mesh 122 in FIG. 1, the heater 136 and RF mesh may be oriented in any suitable orientation to heat the substrate 101, e.g., heater 136 below the RF mesh 122.

In some embodiments, the ceramic composition includes one or more metal compounds. In at least one embodiment, the ceramic composition includes a metal compound having a Group 13 metal, such as aluminum, gallium, and/or indium. The Group 13 metal based compound may include any one or more aluminum based compounds, such as an aluminum oxide, aluminum nitride, aluminum oxynitride, aluminum fluoride, and/or aluminum oxy-fluoride. In at least one embodiment, the Group 13 metal based compound includes aluminum oxide, aluminum nitride, or a combination thereof. Without being bound by theory, ceramic compositions including aluminum oxide can exhibit increased hardness over other ceramic compositions. Furthermore, including aluminum nitride in ceramic compositions can provide increased electrical resistivity. Additionally, including an oxy-fluoride (e.g., aluminum oxy-fluoride) in ceramic compositions can enhance the fluorine etch resistivity and overall etch resistance.

In some embodiments, the one or more metal compounds of the ceramic composition includes an alkaline-earth metal based compound. The alkaline-earth metal based compound may include a compound having a Group 2 metal, such as beryllium, magnesium, calcium, strontium, barium, or radium. In at least one embodiment, the alkaline-earth metal based compound includes a magnesium based compound, such as magnesium oxide, magnesium nitride, magnesium oxynitride, magnesium fluoride, and/or magnesium oxy-fluoride. The alkaline-earth metal based compound may include magnesium oxide, magnesium fluoride, calcium oxide, calcium fluoride, strontium oxide, strontium fluoride, barium oxide, barium fluoride, or a combination thereof. Without being bound by theory, ceramic compositions including magnesium oxide, calcium oxide, barium oxide, or strontium oxide can exhibit reduced vapor pressure and low wear rate for NF₃ plasma processing techniques operating at temperatures of less than 600° C. Additionally, and without being bound by theory, an alkaline-earth metal based compound including an oxyfluoride can enhance fluorine etch resistivity, thereby promoting etch resistance in the ceramic composition.

In some embodiments, the one or more metal compounds of the ceramic composition include a rare earth metal based compound. The rare earth metal based compound may include a Group 3-12 metal, such as erbium, lanthanum, samarium, yttrium, scandium, or a combination thereof. In at least one embodiment, the rare earth metal based compound includes yttrium oxide, yttrium nitride, yttrium oxynitride, yttrium fluoride, yttrium oxy-fluoride, lanthanum oxide, lanthanum nitride, lanthanum oxynitride, lanthanum fluoride, lanthanum oxy-fluoride, erbium oxide, erbium nitride, erbium oxynitride, erbium fluoride, erbium oxy-fluoride, samarium oxide, samarium nitride, samarium oxynitride, samarium fluoride, samarium oxy-fluoride, scandium oxide, scandium nitride, scandium oxynitride, scandium fluoride, scandium oxy-fluoride, and combinations thereof. Without being bound by theory, ceramic compositions including a rare earth metal compound can exhibit a reduced vapor pressure, a reduced leakage current, an enhanced electrical resistivity, a reduced dielectric loss to prevent radiofrequency self-heating, a reduced wear rate, and/or an enhanced dielectric breakdown voltage when compared to conventional ceramic compositions. Without being bound by theory, a rare earth based metal compound including an oxyfluoride can enhance fluorine etch resistivity, thereby promoting etch resistance in the ceramic composition.

In some embodiments, the ceramic composition includes a compound and/or material intended to modify the coefficient of thermal expansion (CTE) of the resulting ceramic material. The CTE modifying compound may include a negative thermal expansion (NTE) material, such as a metal oxide NTE, a metal cyanide NTE, a PbTiO₃ (PT)-based perovskite compound, a Mn₃AN/C-based anti-perovskite compound, an iron alloy system (e.g., Invar alloys), low-dimensional materials (e.g., graphite and graphene), metal-organic frameworks (MOFs) and/or polymers, and a metal fluoride. In at least one embodiment, the CTE modifying compound includes a metal fluoride compound. The metal fluoride compound may be represented by AFₓ, wherein A is a metal atom, F is fluorine, and x is an integer. In at least one embodiment, A is selected from Sc, Zn, Ti, Mn, Ca, Y, Mg, and Ba. In at least one embodiment, x is either 1, 2, or 3. The metal fluoride compound may be selected from ScF₃, CaF₂, YF₃, BaF₂, ZnF₂, TiF₃, MgF₂ and combinations thereof. Without being bound by theory, including a CTE modifier in a ceramic composition enables the CTE to be tailored to the resulting composition in order to alleviate thermal stresses that may be incurred during various thermal and/or plasma processing techniques.

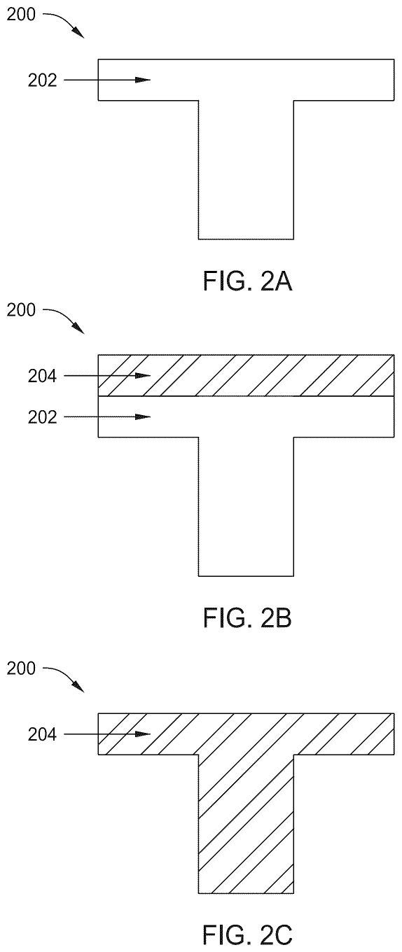

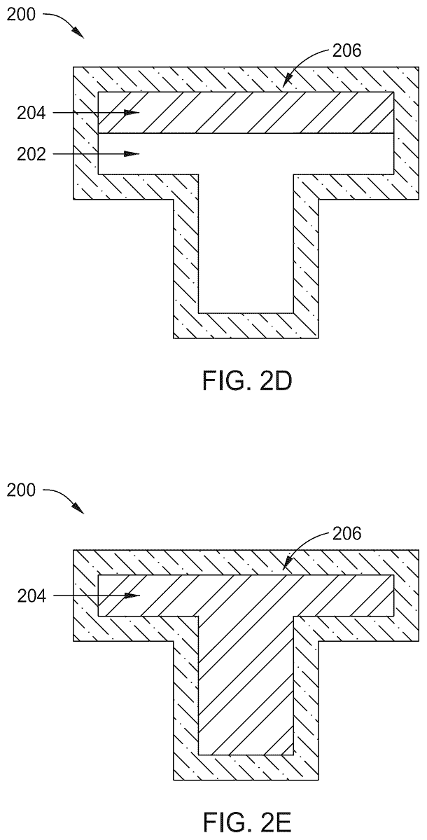

In some embodiments, the ceramic composition includes one or more of a Group 13 metal based compound, an alkaline-earth metal based compound, a rare earth metal based compound, a CTE modifying compound, or a combination thereof. The ceramic composition may be modified to attain a ceramic material having a modified CTE for a specific use and/or purpose. FIG. 2A shows a schematic, side view of a ceramic part 200 made of a conventional ceramic material 202 (e.g., aluminum nitride) used in a processing chamber. As previously described, the process chamber 100 can include one or more ceramic parts 200 including lift pins, edge rings, isolators, heaters, electrostatic chucks, and/or baffles, in which each of the one or more lift pins, edge rings, isolators, heaters, electrostatic chucks, and/or baffles include a ceramic composition of the present disclosure. In some embodiments, the heater 136 or electrostatic chuck may be a ceramic part 200 of the present disclosure. As such, ceramic compositions of the present disclosure may be tailored, via alterations in ceramic compositions, for use in a processing chamber.

FIG. 2B shows a schematic, side view of a ceramic part 200 used in a processing chamber. In some embodiments, the ceramic composition 204 of the present disclosure is deposited as a layer onto a surface of a ceramic part 200 of the processing chamber 100 and may be fused thereto, the ceramic part 200 being made of a different material (e.g., a conventional ceramic material 202). The ceramic composition 204 may be modified to attain a modified CTE similar to that of the conventional ceramic material 202 in order to minimize the CTE mismatch at the interface of the ceramic composition 204 and the conventional ceramic material 202.

For example, the ceramic composition 204 may be tailored to provide a modified CTE that matches, or is greater than, the CTE of the conventional ceramic material 202 (e.g., aluminum nitride). Such modified CTE values may allow for increased bonding between the conventional ceramic material 202 and the ceramic composition 204 deposited thereon, under predetermined plasma processing conditions. Additionally and/or alternatively, the CTE modifying compound present within the ceramic composition 204 can act as a flux and/or sintering aid, further improving bonding between the conventional ceramic material 202 and the ceramic composition 204.

In some embodiments, a ceramic part 200 including a ceramic composition 204 deposited over the conventional ceramic material 202, as described in the context of FIG. 2B, includes a layer thickness of about 0.5 mm to about 5 mm, such as about 1 mm to about 4 mm, such as about 2 mm to about 3 mm, alternatively about 0.5 mm to about 1 mm, alternatively about 1 mm to about 2 mm, alternatively about 2 mm to about 2.5 mm, alternatively about 2.5 mm to about 3 mm, alternatively about 3 mm to about 4 mm, alternatively about 4 mm to about 5 mm. In at least one embodiment, a ceramic part 200 of the processing chamber 100 is made from the ceramic composition 204 of the present disclosure, as shown in FIG. 2C.

Ceramic compositions of the present disclosure may include a Group 13 metal based compound, an alkaline-earth metal based compound, a rare earth metal based compound, and/or a CTE modifying compound. In some embodiments, the ceramic composition has a modified CTE of about 3 ppm/° C. (parts per million per degree Celsius) to about 18 ppm/° C., such as about 5 ppm/° C. to about 15 ppm/° C., such as about 8 ppm/° C. to about 12 ppm/° C., alternatively about 3 ppm/° C. to about 5 ppm/° C., alternatively about 5 ppm/° C. to about 8 ppm/° C., alternatively about 8 ppm/° C. to about 10 ppm/° C., alternatively about 10 ppm/° C. to about 12 ppm/° C., alternatively about 12 ppm/° C. to about 15 ppm/° C., alternatively about 15 ppm/° C. to about 18 ppm/° C. Without being bound by theory, the components implemented in the ceramic composition can be used to estimate the resulting modified CTE via Formula (I):

$$α \approx ( {X}_{mol \%} * {X}_{CTE} ) + ( {Y}_{mol \%} * {Y}_{CTE} ) + ( {Z}_{mol \%} * {Z}_{CTE} ) + ( {γ}_{mol \%} * {γ}_{CTE} ) \qquad ( I )$$

wherein α is the resulting modified CTE, X_{mol %} is the amount of the Group 13 metal based compound present in the ceramic composition, X_{CTE} is the CTE of the metal compound having a Group 13 metal, Y_{mol %} is the amount of the alkaline-earth metal based compound present in the ceramic composition, Y_{CTE} is the CTE of the alkaline-earth metal based compound, Z_{mol %} is the amount of the rare earth metal based compound present in the ceramic composition, Z_{CTE} is the CTE of the rare earth metal based compound, γ_{mol %} is the amount of the CTE modifying compound present in the ceramic composition, and γ_{CTE} is the CTE of the CTE modifying compound.

In some embodiments, the ceramic composition includes about 0 mol % to about 100 mol % of the Group 13 metal based compound, such as about 20 mol % to about 80 mol %, such as about 40 mol % to about 60 mol %, alternatively about 0 mol % to about 20 mol %, alternatively about 20 mol % to about 40 mol %, alternatively about 40 mol % to about 50 mol %, alternatively about 50 mol % to about 60 mol %, alternatively about 60 mol % to about 80 mol %, alternatively about 80 mol % to about 100 mol %. In some embodiments, the Group 13 metal based compound has a CTE of about 10 ppm/° C. to about 15 ppm/° C., such as about 11 ppm/° C. to about 14 ppm/° C., such as about 12 ppm/° C. to about 13 ppm/° C., alternatively about 10 ppm/° C. to about 11 ppm/° C., alternatively about 11 ppm/° C. to about 12 ppm/° C., alternatively about 12 ppm/° C. to about 12.5 ppm/° C., alternatively about 12.5 ppm/° C. to about 13 ppm/° C., alternatively about 13 ppm/° C. to about 14 ppm/° C., alternatively about 14 ppm/° C. to about 15 ppm/° C.

In some embodiments, the ceramic composition includes about 0 mol % to about 100 mol % of the alkaline-earth metal based compound, such as about 20 mol % to about 80 mol %, such as about 40 mol % to about 60 mol %, alternatively about 0 mol % to about 20 mol %, alternatively about 20 mol % to about 40 mol %, alternatively about 40 mol % to about 50 mol %, alternatively about 50 mol % to about 60 mol %, alternatively about 60 mol % to about 80 mol %, alternatively about 80 mol % to about 100 mol %. In some embodiments, the alkaline-earth metal based compound has a CTE of about 8 ppm/° C. to about 15 ppm/° C., such as about 10 ppm/° C. to about 13 ppm/° C., such as about 11 ppm/° C. to about 12 ppm/° C., alternatively about 8 ppm/° C. to about 10 ppm/° C., alternatively about 10 ppm/° C. to about 11 ppm/° C., alternatively about 11 ppm/° C. to about 11.5 ppm/° C., alternatively about 11.5 ppm/° C. to about 12 ppm/° C., alternatively about 12 ppm/° C. to about 13 ppm/° C., alternatively about 13 ppm/° C. to about 15 ppm/° C.

In some embodiments, the ceramic composition includes about 0 mol % to about 100 mol % of the rare earth metal based compound, such as about 20 mol % to about 80 mol %, such as about 40 mol % to about 60 mol %, alternatively about 0 mol % to about 20 mol %, alternatively about 20 mol % to about 40 mol %, alternatively about 40 mol % to about 50 mol %, alternatively about 50 mol % to about 60 mol %, alternatively about 60 mol % to about 80 mol %, alternatively about 80 mol % to about 100 mol %. In some embodiments, the rare earth metal based compound has a CTE of about 6 ppm/° C. to about 30 ppm/° C., such as about 10 ppm/° C. to about 25 ppm/° C., such as about 17.5 ppm/° C. to about 22.5 ppm/° C., alternatively about 6 ppm/° C. to about 10 ppm/° C., alternatively about 10 ppm/° C. to about 17.5 ppm/° C., alternatively about 17.5 ppm/° C. to about 20 ppm/° C., alternatively about 20 ppm/° C. to about 22.5 ppm/° C., alternatively about 22.5 ppm/° C. to about 25 ppm/° C., alternatively about 25 ppm/° C. to about 30 ppm/° C.

In some embodiments, the ceramic composition includes about 0.01 mol % to about 25 mol % of the CTE modifying compound, such as about 0.1 mol % to about 20 mol %, such as about 1 mol % to about 15 mol %, such as about 5 mol % to about 10 mol %, alternatively about 0.01 mol % to about 0.1 mol %, alternatively about 0.1 mol % to about 1 mol %, alternatively about 1 mol % to about 5 mol %, alternatively about mol % 5 to about 7.5 mol %, alternatively about 7.5 mol % to about 10 mol %, alternatively about 10 mol % to about 15 mol %, alternatively about 15 mol % to about 20 mol %, alternatively about 20 mol % to about 25 mol %. In some embodiments, the CTE modifying compound has a CTE of about-2 ppm/° C. to about-15 ppm/° C., such as about-5 ppm/° C. to about-12 ppm/° C., such as about-8 ppm/° C. to about-10 ppm/° C., alternatively about-2 ppm/° C. to about-5 ppm/° C., alternatively about-5 ppm/° C. to about-8 ppm/° C., alternatively about −8 ppm/° C. to about-9 ppm/° C., alternatively about-9 ppm/° C. to about-10 ppm/° C., alternatively about-10 ppm/° C. to about-12 ppm/° C., alternatively about-12 ppm/° C. to about-15 ppm/° C.

In some embodiments, the ceramic composition includes a Group 13 metal based compound, an alkaline-earth metal based compound, a rare earth metal based compound, and a CTE modifying compound. The Group 13 metal based compound may include an aluminum based compound, such as an aluminum oxide, aluminum nitride, aluminum oxynitride, aluminum fluoride, and/or aluminum oxy-fluoride. In at least one embodiment, the Group 13 metal based compound includes Al₂O₃. The alkaline-earth metal based compound may include a compound having a Group 2 metal, such as beryllium, magnesium, calcium, strontium, barium, or radium. In at least one embodiment, the alkaline-earth metal based compound includes MgO. The rare earth metal based compound may include a compound having a Group 3-12 metal, such as erbium, lanthanum, samarium, yttrium, scandium, or a combination thereof. In at least one embodiment, the rare earth metal based compound includes Y₂O₃. The CTE modifying compound may include a NTE material. In at least one embodiment, the CTE modifying compound includes ScF₃.

In at least one embodiment, the ceramic composition includes about 0 mol % to about 100 mol % of Al₂O₃, such as about 20 mol % to about 80 mol %, such as about 40 mol % to about 60 mol %, alternatively about 0 mol % to about 20 mol %, alternatively about 20 mol % to about 40 mol %, alternatively about 40 mol % to about 50 mol %, alternatively about 50 mol % to about 60 mol %, alternatively about 60 mol % to about 80 mol %, alternatively about 80 mol % to about 100 mol %. In at least one embodiment, the ceramic composition includes about 0 mol % to about 100 mol % of MgO, such as about 20 mol % to about 80 mol %, such as about 40 mol % to about 60 mol %, alternatively about 0 mol % to about 20 mol %, alternatively about 20 mol % to about 40 mol %, alternatively about 40 mol % to about 50 mol %, alternatively about 50 mol % to about 60 mol %, alternatively about 60 mol % to about 80 mol %, alternatively about 80 mol % to about 100 mol %. In at least one embodiment, the ceramic composition includes about 0 mol % to about 100 mol % of Y₂O₃, such as about 20 mol % to about 80 mol %, such as about 40 mol % to about 60 mol %, alternatively about 0 mol % to about 20 mol %, alternatively about 20 mol % to about 40 mol %, alternatively about 40 mol % to about 50 mol %, alternatively about 50 mol % to about 60 mol %, alternatively about 60 mol % to about 80 mol %, alternatively about 80 mol % to about 100 mol %. In at least one embodiment, the ceramic composition includes about 0.01 mol % to about 25 mol % of ScF₃, such as about 0.1 mol % to about 20 mol %, such as about 1 mol % to about 15 mol %, such as about 5 mol % to about 10 mol %, alternatively about 0.01 mol % to about 0.1 mol %, alternatively about 0.1 mol % to about 1 mol %, alternatively about 1 mol % to about 5 mol %, alternatively about mol % 5 to about 7.5 mol %, alternatively about 7.5 mol % to about 10 mol %, alternatively about 10 mol % to about 15 mol %, alternatively about 15 mol % to about 20 mol %, alternatively about 20 mol % to about 25 mol %.

FIG. 2D shows a schematic, side view of a ceramic part 200 used in a processing chamber 100. In some embodiments, a ceramic part 200 used in a processing chamber 100 may include a layer of the ceramic composition 204 disposed over a surface of a conventional ceramic material 202, such as that previously described in FIG. 2B, and a fluoride glass glaze 206 covering the outer surface of the ceramic part 200. FIG. 2E shows a schematic, side view of a ceramic part 200 used in a processing chamber 100. In some embodiments, a ceramic part 200 used in a processing chamber 100 may include a ceramic part made of the ceramic composition 204, such as such as the ceramic part 200 previously described in FIG. 2C, and a fluoride glass glaze 206 covering the outer surface of the ceramic part 200. In some embodiments, the fluoride glass glaze 206 includes a Group 13 metal based compound, an alkaline-earth metal based compound, a rare earth metal based compound, and one or more CTE modifying compounds. Without being bound by theory, the fluoride glass glaze 206 can be used as a flux/sintering aid. Furthermore, the fluoride glass glaze 206 can add fluorine to the ceramic composition to provide increased fluorine resistance.

The fluoride glass glaze 206 may include a Group 13 metal based compound, an alkaline-earth metal based compound, a rare earth metal based compound, and one or more CTE modifying compounds. In some embodiments, the fluoride glass glaze 206 has a CTE of about-15 ppm/° C. to about 40 ppm/° C., such as about-10 ppm/° C. to about 30 ppm/° C., such as about 0 ppm/° C. to about 20 ppm/° C., such as about 5 ppm/° C. to about 15 ppm/° C., alternatively about-15 ppm/° C. to about-10 ppm/° C., alternatively about −10 ppm/° C. to about 0 ppm/° C., alternatively about 0 ppm/° C. to about 5 ppm/° C., alternatively about 5 ppm/° C. to about 10 ppm/° C., alternatively about 10 ppm/° C. to about 15 ppm/° C., alternatively about 15 ppm/° C. to about 20 ppm/° C., alternatively about 20 ppm/° C. to about 30 ppm/° C., alternatively about 30 ppm/° C. to about 40 ppm/° C. Without being bound by theory, the components implemented in the fluoride glass glaze 206 can be used to estimate the resulting CTE via Formula (II):

$${α}^{′} \approx ( {X}_{mol \%} * {X}_{CTE} ) + ( {Y}_{mol \%} * {Y}_{CTE} ) + ( {Z}_{mol \%} * {Z}_{CTE} ) + Σ [ ( {γ}_{mol \%} * {γ}_{CTE} ) ] \qquad ( II )$$

wherein α′ is the resulting fluoride glass glaze CTE, X_{mol %} is the amount of the Group 13 metal based compound present in the ceramic composition, X_{CTE} is the CTE of the Group 13 metal based compound, Y_{mol %} is the amount of the alkaline-earth metal based compound present in the ceramic composition, Y_{CTE} is the CTE of the alkaline-earth metal based compound, Z_{mol %} is the amount of the rare earth metal based compound present in the ceramic composition, Z_{CTE} is the CTE of the rare earth metal based compound, γ_{mol %} is the amount of a CTE modifying compound present in the ceramic composition, and Y_{CTE} is the CTE of a CTE modifying compound. For example, a fluoride glass glaze 206 composition may include a Group 13 metal based compound (X′), an alkaline-earth metal based compound (Y′), a rare earth metal based (Z′), a first CTE modifying compound (γ′), a second CTE modifying compound (γ″), and a third CTE modifying compound (γ″) wherein α′ can be estimated by α′≈(X′_{mol %}*X′_{CTE})+(Y′_{mol %}*Y′_{CTE})+(Z′_{mol %}*Z′_{CTE})+(γ′_{mol %}*γ′_{CTE})+(γ″_{mol %}*Y″_{CTE})+(γ′″_{mol %}*γ″_{CTE}).

In some embodiments, a fluoride glass glaze 206 may deposited over the surface of the ceramic part 200 of the processing chamber 100, as shown in FIG. 2D and FIG. 2E. The fluoride glass glaze 206 may have a thickness up to about 1 mm, such as about 0.01 mm to about 1 mm, such as about 0.1 mm to about 1 mm, such as about 0.5 mm to about 1 mm.

The present disclosure relates to ceramic compositions for use in high temperature plasma processing chambers. The ceramic compositions described herein exhibit resistance to harsh thermal and chemical processing conditions (e.g., high temperatures, fluorine exposure, and plasma exposure), such as those implemented/utilized in semiconductor processing and manufacturing. The ceramic compositions of the present disclosure can include a Group 13 metal based compound (e.g., Al₂O₃), an alkaline-earth metal based compound (e.g., MgO), a rare earth metal base compound (e.g., Y₂O₃), and a CTE modifying compound (e.g., ScF₃). The ceramic composition of the present disclosure can be tailored to attain a modified CTE favorable for an intended application. Additionally, CTE modifying compound can include a NTE material allowing for greater CTE control and tunability.

While the foregoing is directed to embodiments of the present disclosure, other and further embodiments of the disclosure may be devised without departing from the basic scope thereof, and the scope thereof is determined by the claims that follow.

What is claimed is:

1. A ceramic composition, comprising:
a Group 13 metal based compound;
an alkaline-earth metal based compound;
a rare earth metal based compound; and
a coefficient of thermal expansion (CTE) modifying compound.

2. The ceramic composition of claim 1, wherein the Group 13 metal based compound is selected from the group consisting of aluminum oxide, aluminum nitride, aluminum oxynitride, aluminum fluoride, aluminum oxy-fluoride, and combinations thereof.

3. The ceramic composition of claim 1, wherein the ceramic composition further comprises a modified CTE of about 3 ppm/° C. (parts per million per degree Celsius) to about 18 ppm/° C.

4. The ceramic composition of claim 1, wherein the Group 13 metal based compound is present in the composition in an amount of about 20 mol % to about 80 mol %.

5. The ceramic composition of claim 1, wherein the alkaline-earth metal based compound is selected from the group consisting of magnesium oxide, magnesium fluoride, calcium oxide, calcium fluoride, strontium oxide, strontium fluoride, barium oxide, barium fluoride, and combinations thereof.

6. The ceramic composition of claim 1, wherein the alkaline-earth metal based compound is MgO.

7. The ceramic composition of claim 1, wherein the alkaline-earth metal based compound is present in the composition in an amount of about 20 mol % to about 80 mol %.

8. The ceramic composition of claim 1, wherein the CTE modifying compound is selected from the group consisting of ScF₃, CaF₂, YF₃, BaF₂, ZnF₂, TiF₃, MgF₂ and combinations thereof.

9. The ceramic composition of claim 1, wherein the CTE modifying compound is ScF₃.

10. The ceramic composition of claim 1, wherein the CTE modifying compound is present in the composition in an amount of about 0.01 mol % to about 25 mol %.

11. A component of a plasma processing chamber, comprising:
an outer surface comprising a ceramic composition, the ceramic composition comprising:
a Group 13 metal based compound;
an alkaline-earth metal based compound;
a rare earth metal based compound; and
a coefficient of thermal expansion (CTE) modifying compound.

12. The component of claim 11, wherein the Group 13 metal based compound is selected from the group consisting of aluminum oxide, aluminum nitride, aluminum oxynitride, aluminum fluoride, aluminum oxy-fluoride, and combinations thereof.

13. The component of claim 11, wherein the Group 13 metal based compound is present in the ceramic composition in an amount of about 20 mol % to about 80 mol %.

14. The component of claim 11, wherein the alkaline-earth metal based compound is selected from the group consisting of magnesium oxide, calcium oxide, strontium oxide, barium oxide, and combinations thereof.

15. The component of claim 11, wherein the alkaline-earth metal based compound is MgO.

16. The component of claim 11, wherein the alkaline-earth metal based compound is present in the ceramic composition in an amount of about 20 mol % to about 80 mol %.

17. The component of claim 11, wherein the CTE modifying compound is selected from the group consisting of ScF₃, CaF₂, YF₃, BaF₂, ZnF₂, TiF₃, MgF₂ and combinations thereof.

18. The component of claim 11, wherein the CTE modifying compound is ScF₃.

19. The component of claim 11, wherein the CTE modifying compound is present in the ceramic composition in an amount of about 0.01 mol % to about 25 mol %.

20. The component of claim 11, wherein the component is selected from the group consisting of lift pins, edge rings, isolators, heaters, electrostatic chucks, nozzles, and baffles.
